(19) United States
(12) Patent Application Publication
(10) Pub. No.: US 2026/0367504 A1
(43) Pub. Date: Nov. 19, 2026

(54) SYSTEM FOR MOUNTING PELLICLE ON MASK AND METHOD OF OPERATING THE SAME

(71) Applicant: Taiwan Semiconductor Manufacturing Co., Ltd., Hsinchu (TW)

(72) Inventors: Hung-Jui CHANG, Hsinchu (TW); Tzu Han LIU, Hsinchu (TW); Chih-Wei WEN, Hsinchu (TW)

(73) Assignee: Taiwan Semiconductor Manufacturing Co., Ltd., Hsinchu (TW)

(21) Appl. No.: 19/208,378

(22) Filed: May 14, 2025

(51) Int. Cl. G03F 1/62; G03F 9/00

(52) U.S. Cl. CPC G03F 1/62; G03F 9/7088

(57) ABSTRACT

The present disclosure is directed to a system including one or more detectors configured to, in operation, determine a position of a pellicle at, on, and along a surface of a pellicle case. A processor is in electrical communication with eh one or more detectors and determines whether the pellicle is properly positioned before engaging the pellicle with a clamp component to remove the pellicle from the pellicle case and mounting the pellicle to a surface of a mask. The pellicle includes a plurality of sidewalls one or more marks that are to be detected by the one or more detectors are at and along one or more respective sidewalls of the plurality of sidewalls. The one or more marks are utilized to determine the position of the pellicle when present at, on, and along the surface of the pellicle case.

### BACKGROUND

While manufacturing semiconductor devices (i.e., semiconductor packages, semiconductor substrates, semiconductor dice or other similar or like types of semiconductor devices), workpieces (e.g., semiconductor substrates, semiconductor wafers, multilayer structures, or some other suitable type of workpieces) are refined or patterned by utilizing a photolithography process (e.g., an EUV (extreme ultraviolet) lithography process or some other suitable type of photolithography process) to refine or pattern respective surfaces of the workpieces. In performing this photolithography process, a pellicle is mounted to a photomask, and the photomask includes a surface that has a pattern. The pellicle is configured to, in operation, to act as a barrier to prevent contaminants (i.e., particles) from reaching the photomask preventing damage to the surface of the photomask that has the pattern. The pellicle is mounted to the photomask with a mounting process in which the photomask is removed from a pellicle case containing one or more pellicles by a pellicle clamp and is then coupled to the photomask such that the pellicle covers the surface of the photomask with the pellicle. Then after the pellicle is coupled to the photomask the photolithography process is carried out in which the photomask is exposed to an incident light provided by a light source resulting in a respective surface of a workpiece being patterned with the pattern along the surface of the photomask. As set forth earlier, during this photolithography process, the surface of the photomask with the pattern is protected from contaminants from within a photolithography chamber that could be generated from carrying out the photolithography process from reaching the surface of the photomask with the pattern. However, if the pellicle is not positioned within tolerances when mounted to the photomask, while the pellicle may still protect the surface of the photomask with the pattern, the mis-mounting of the pellicle to the photomask can damage the photomask or can result in the photolithography process not being carried out accurately resulting in the respective surface of the respective workpiece being patterned outside of manufacturing tolerances.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is directed to a flowchart of a method of mounting a pellicle to a photomask.

FIG. 2A is a top side view of a respective step of the method of mounting the pellicle to the photomask as shown in FIG. 1.

FIG. 2B is a top side view of a respective step of the method of mounting the pellicle to the photomask as shown in FIG. 1.

FIG. 2C is a top side view of a respective step of the method of mounting the pellicle to the photomask as shown in FIG. 1.

FIG. 2D is a top side view of the pellicle mounted to the photomask after completing the method of mounting the pellicle to the photomask as shown in FIG. 1.

FIG. 3A is a perspective view of a pellicle, in accordance with some embodiments.

FIG. 3B is a zoomed in, side view of a respective side of the pellicle as shown in FIG. 3A, in accordance with some embodiments.

FIG. 4 is a perspective view of a system for detecting one or more respective marks on the pellicle as shown in FIGS. 3A and 3B, in accordance with some embodiments.

FIG. 5A is a top side view of a pellicle case, in accordance with some embodiments.

FIG. 5B is a top side view of a pellicle case, in accordance with some embodiments.

FIG. 5C is a top side view of a pellicle case, in accordance with some embodiments.

FIG. 5D is a top side view of a pellicle case, in accordance with some embodiments.

FIG. 5E is a top side view of a pellicle case, in accordance with some embodiments.

FIG. 5F is a top side view of a pellicle case, in accordance with some embodiments.

FIG. 5G is a top side view of a pellicle case, in accordance with some embodiments.

FIG. 6 is a perspective view of a system for detecting a position of a pellicle within a pellicle case, in accordance with some embodiments.

FIG. 7 is a flowchart of a method of calibrating a position of a pellicle within a pellicle case and mounting the pellicle to a mask, in accordance with some embodiments.

FIG. 8A is a top side view of a system with respect to a respective step of the method of calibrating the position of the pellicle within the pellicle case and mounting the pellicle to the mask as shown in FIG. 7, in accordance with some embodiments.

FIG. 8B is a top side view of a system with respect to a respective step of the method of calibrating the position of the pellicle within the pellicle case and mounting the pellicle to the mask as shown in FIG. 7, in accordance with some embodiments.

FIG. 8C is a top side view of a system with respect to a respective step of the method of calibrating the position of the pellicle within the pellicle case and mounting the pellicle to the mask as shown in FIG. 7, in accordance with some embodiments.

FIG. 8D is a side view of a system with respect to a respective step of the method of calibrating the position of the pellicle within the pellicle case and mounting the pellicle to the mask as shown in FIG. 7, in accordance with some embodiments.

FIG. 8E is a side view of a system with respect to a respective step of the method of calibrating the position of the pellicle within the pellicle case and mounting the pellicle to the mask as shown in FIG. 7, in accordance with some embodiments.

FIG. 8F is a top side view of a system with respect to a respective step of the method of calibrating the position of the pellicle within the pellicle case and mounting the pellicle to the mask as shown in FIG. 7, in accordance with some embodiments.

FIG. 8G is a top side view of the pellicle mounted to the mask after the method of calibrating the position of the pellicle within the pellicle case and mounting the pellicle to the mask as shown in FIG. 7, in accordance with some embodiments.

FIG. 9A is a top side view of a system with respect to a respective step of a method of calibrating the position of the pellicle within an alternative embodiment of a pellicle case and mounting the pellicle to the mask as shown in FIG. 7, in accordance with some embodiments.

FIG. 9B is a side view of a system with respect to a respective step of a method of calibrating the position of the pellicle within the alternative embodiment of the pellicle case and mounting the pellicle to the mask as shown in FIG. 7, in accordance with some embodiments.

FIG. 9C is a side view of a system with respect to a respective step of a method of calibrating the position of the pellicle within the alternative embodiment of the pellicle case and mounting the pellicle to the mask as shown in FIG. 7, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

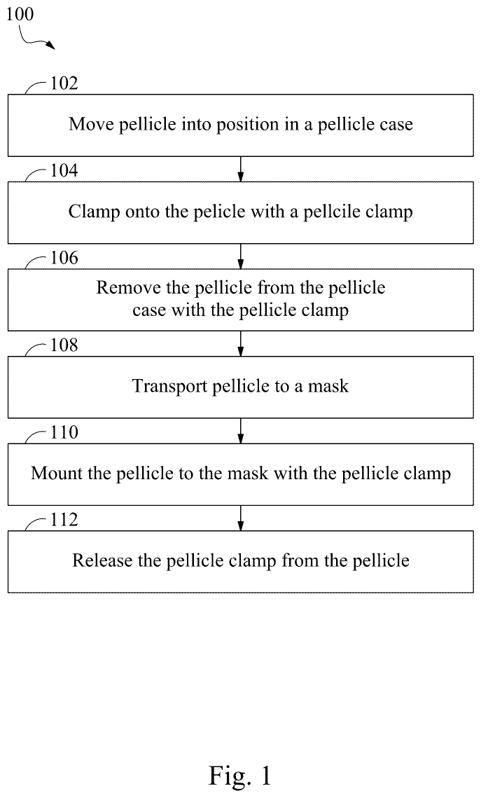

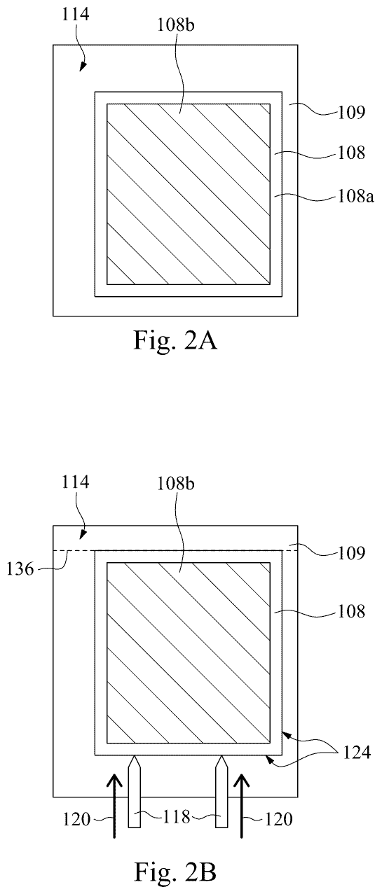

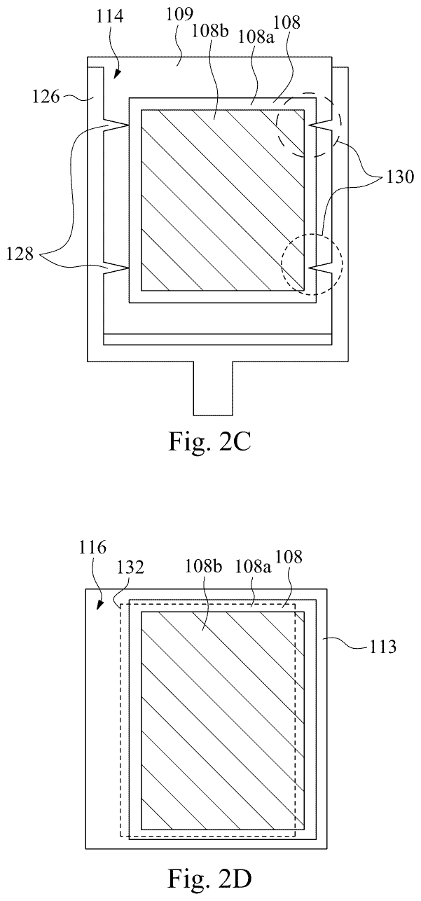

FIG. 1 is directed to a flowchart 100 of a method of mounting including respective steps 102, 104, 106, 108, 110, 112 to mount a pellicle 108 (see FIG. 2A of the present disclosure) to a photomask 113 (see FIG. 2D of the present disclosure). The flowchart 100 includes a first step 102, a second step 104, a third step 106, a fourth step 108, a fifth step 110, and a sixth step 112. FIGS. 2A-2C are top side views of at least some of the respective steps of the method of mounting of the flowchart 100 as shown in FIG. 1. Accordingly, the details of FIGS. 2A-2C will be discussed as follows herein with respect to the respective steps 102, 104, 106, 108, 110, 112 of the flowchart 100 of the method of mounting the pellicle 108 to the photomask 113.

As shown in FIG. 2A, the pellicle 108 is resting within a pellicle case 109. The pellicle 108 is resting on a surface 114 of the pellicle case 109. While not shown, the surface 114 of the pellicle case 109 may be a surface of a shelf of the pellicle case 109, and the shelf may be on shelf of a plurality of shelfs such that the pellicle case 109 is capable of containing multiple pellicles. Alternatively, the pellicle case 109 may be structured to only contain the pellicle 108 alone and no other respective pellicles. The pellicle 108 includes a frame 108a and a pellicle membrane 108b that is coupled to the frame 108a. The frame 108a is relatively stiff and rigid as compared to the pellicle membrane 108b and provides support to the pellicle membrane 108b.

The frame 108a of the pellicle 108 is configured to, in operation, be mounted to a surface 116 of the photomask 113 (see FIG. 2D of the present disclosure). For example, the frame 108a of the pellicle 108 is mounted to or coupled to the surface 116 of the photomask 113 by an adhesive or by some other suitable technique for mounting or coupling the frame 108a of the pellicle 108 to the surface 116 of the photomask 113. When the frame 108a is of the pellicle 108 of the surface 116 of the photomask 113, the pellicle membrane 108b is configured to, in operation, protect and cover a pattern along the surface 116 of the photomask 113. In other words, the pellicle membrane 108b is configured to, in operation, act as a barrier to prevent contaminant particles from reaching the pattern preventing or reducing the likelihood of the pattern along the surface 116 of the photomask 113 from being damaged when carrying out a photolithography process.

As shown in FIG. 2A, the pellicle 108 is slightly offset from a center of the pellicle case 109. This offset positioning of the pellicle 108 generally increases a likelihood of the pellicle 108 being mis-positioned when mounted to or coupled to the photomask 113. This mis-positioning of the pellicle 108 when mounted to or coupled to the photomask 113 increases a likelihood of or causes damage to the pattern along the surface 116 of the photomask 113. Alternatively, this mis-positioning of the pellicle 108 when mounted to or coupled to the photomask 113 increases a likelihood of or causes a photolithography process to be performed outside of manufacturing tolerances resulting in a respective surface of a workpiece being patterned outside of manufacturing tolerances generating yield loss within a semiconductor manufacturing plant (FAB) increases operation costs of the FAB.

In the first step 102, the pellicle 108 is moved to a position by a pair of push components 118 as shown in FIG. 2B. The pair of push components 118 are only moveable in a direction as represented by arrows 120 based on the orientation as shown in FIG. 2B and are only moveable together. In other words, the pair of push components 118 are not movable individually and are not movable in a horizontal direction based on the orientation as shown in FIG. 2B. The pair of push components 118 have respective pointed ends 122 that are configured to, in operation, contacts a respective sidewall or respective edge of a plurality of sidewalls or edges 124 of the frame 108a of the pellicle 108 that define a periphery of the pellicle 108 to push the pellicle 108 into position to be removed from the pellicle case 109. As shown in FIG. 2B, the pair of push components 118 push on the lower sidewall 124 of the frame 108a of the pellicle 108 based on the orientation as shown in FIG. 2B. The pair of push components 118 push the pellicle 108 such that the upper sidewall 124 is aligned with a dotted line 123 representing the position in which the pellicle 108 is to be positioned within the pellicle case 108 before being removed from the pellicle case. However, as the pair of push components 118 are in capable of moving the pellicle 108 in the horizontal direction, the pellicle 108 is still horizontally offset even though the pellicle 108 is in the vertically correct position.

After the first step 102 in which the pellicle 108 is moved into position by the pair of push component as shown in FIG. 2B, in the second step 104 a clamp component 126 is brought into engagement with the frame 108a of the pellicle 108 as shown in FIG. 2C. While not shown, in at least one situation, the clamp component 126 is at an end of transfer arm robot (TRA) such that the clamp component 126 can transport pellicles 200 to and from various locations within a workpiece tool or within a semiconductor manufacturing plant (FAB). The clamp component 126 includes a plurality of pins 128 that configured to, in operation, be inserted into pin holes along the plurality of sidewalls or edges 124 of the frame 108a of the pellicle 108. As shown in FIG. 2C, respective pins of the plurality of pins 128 at the right-hand side of the frame 108a of the pellicle 108 encircled by circles 130 are inserted into corresponding pin holes by a greater amount than respective pins of the plurality of pins 128 at the left-hand side of the frame 108a of the pellicle 108. The respective pins of the plurality of pins 128 at the right-hand side are inserted by a greater amount into their corresponding pin holes than the respective pins of the plurality of pins 128 at the left-hand side are inserted into their corresponding pin holes due to the horizontal offset of the pellicle 108 as discussed earlier herein. This results in the clamp component 126 not uniformly and evenly engaging with the right-hand side and the left-hand side of the frame 108a of the pellicle 108.

The respective pins of the plurality of pins 128 at the right-hand side being inserted by a greater amount into the corresponding pin holes at the right-hand side of the frame 108a of the pellicle 108 can result in the frame 108a being damaged resulting in a mis-positioning of the frame 108a when being mounted to the surface 116 of the mask 113. If the frame 108a is damaged,

After the second step 104 in which the clamp component 126 is brought into engagement with the frame 108a of the pellicle 108, in the third step 106 the pellicle 108 is removed from the pellicle case 109 by lifting the pellicle 108 from the surface 114 of the pellicle case 109 and pulling the pellicle 108 out of the pellicle case 108 with the clamp component 126. In other words, the clamp component 126 lifts the pellicle 108 from the surface 114 of the pellicle case 109 to remove the pellicle 108 from the pellicle case 109.

After the third step 106 in which the pellicle 108 is removed from the pellicle case 109 by the clamp component 126, the fourth step 108 the clamp component 126 transports or transfers the pellicle 108 to another location. At this location, the mask 113 is present.

After the fourth step 108 in which the pellicle 108 is transported to the mask 113, in the fifth step 110 the clamp component 126 is utilized to align the pellicle 108 with the mask 113 and the frame 108a of the pellicle 108 is placed on the surface 116 of the mask 108 such that the frame 108a of the pellicle 108 is mounted on the surface 116 of the mask 108 as shown in FIG. 2D. For example, the frame 108a of the pellicle 108 is mounted to and coupled to the surface 116 of the mask 108 by an adhesive. As shown in FIG. 2D, as the clamp component 126 did not uniformly or evenly pick up the pellicle 108 due to respective pins of the plurality of pins 128 being inserted by different amounts into respective pin holes at the right-hand side and the left-hand side of the frame 108a of the pellicle 108, the frame 108a of the pellicle 108 is offset from a mounting position as represented by a dotted rectangle 132. As shown in FIG. 2D, the frame 108a of the pellicle 108 was mounted slightly to the right of the mounting position as represented by the dotted rectangle 132. The frame 108a of the pellicle 108 being offset in this manner generally distorts patterning of a respective surface of a respective workpiece when performing a photolithography process utilizing the pellicle 108 and the mask 113. This distortion in the patterning, which may be referred to as pellicle induced distortion (PID), along the respective surface of the respective workpiece causes or increases a likelihood of semiconductor devices being manufacturing outside of manufacturing tolerances resulting in yield loss and increasing operation costs of a semiconductor manufacturing plant (FAB). Furthermore, if the frame 108a of the pellicle 108 is mis-positioned by enough from the mounting position as represented by the dotted rectangle 132, the frame 108a of the pellicle 108 can actually damage the pattern along the surface 116 of the photomask 113 resulting in the photomask 113 becoming unusable resulting in increased operation costs of the semiconductor manufacturing plant (FAB). Furthermore, when the frame 108a of the pellicle 108 is mis-mounted to the surface 116 of the mask 113, the pellicle membrane 108b can be damaged or there is an increased likelihood that the pellicle membrane 108b is damaged, which can similarly cause distortion to the pattern being transferred from the mask 113 to the respective surface of the workpiece either causing or increasing the likelihood of further yield loss and increasing operating costs of the semiconductor manufacturing plant (FAB).

In view of the above discussion, the present disclosure is directed to reduce the likelihood of mis-positioning the frame 108a when mounting the pellicle 108 to the mask 113 or unevenly and non-uniformly picking up the pellicle 108 such that a yield loss of the semiconductor manufacturing plant (FAB) is reduced and operation costs of the semiconductor manufacturing plant (FAB) are decreased. In other words, by improving or increasing the likelihood that the frame 108a of the pellicle 108 being properly mounted to the surface 116 of the mask 113 and improving or increasing the likelihood of the clamp component 126 evenly and uniformly engaging with the frame 108a of the pellicle 108, the yield number of the semiconductor manufacturing plant (FAB) is increased as there are fewer semiconductor devices that are manufactured outside of manufacturing tolerances, which decreases operation costs and increases profit of the semiconductor manufacturing plant (FAB).

In view of the above discussion, there are tolerances between respective transportation structures, a pellicle case, and a pellicle. The required alignment tolerances between respective pin holes (not shown) along the frame 108a of the pellicle 108 and the pins 128 of clamp 126 are tight. Even after the push components 120 push the pellicle 108 to contact to a roughly aligned position, there still possibly is misalignment between the pin holes (not shown) of the pellicle 108 and the pins 128 of clamp 126. Even with this minor misalignment, when the pins 128 of the clamp 128 are instead inserted into the pin holes (not shown) along the frame 108a, the pins 128 can scratch the frame 108a of pellicle 108 generating contaminants that can damage (e.g., scratch) or contaminate the mask 113 to which the pellicle 108 is to be mounted. The present disclosure is directed to improving alignment of respective pellicles including pin holes to receive the pins 128 of the clamp 126 while reducing the likelihood of generating contaminants or preventing generating contaminants altogether that may damage (e.g., scratch) or contaminate the mask 113 or the pellicle membrane 108b of the pellicle 108.

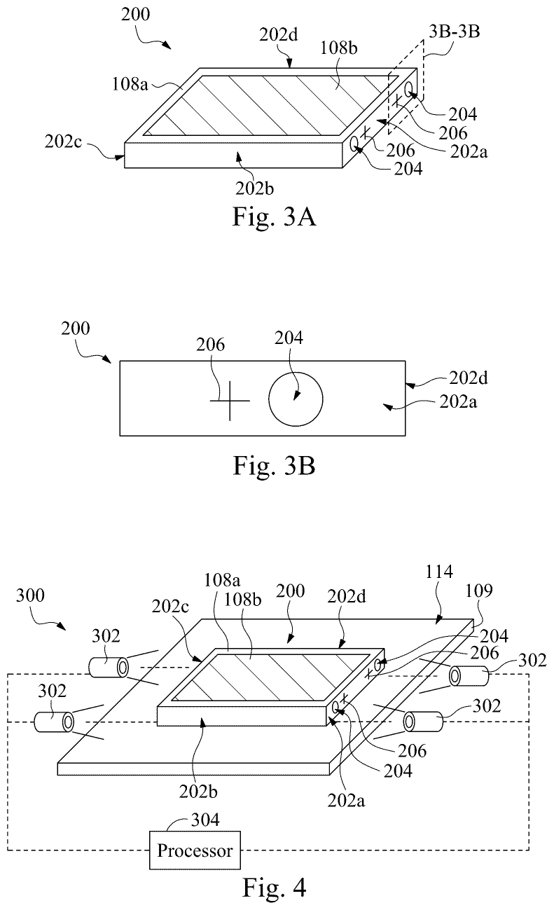

FIG. 3A is a perspective view of a pellicle 200, in accordance with some embodiments. FIG. 3B is a zoomed in enhanced view along a side of the pellicle 200 taken at section 3B-3B as shown in FIG. 3A, in accordance with some embodiments.

The pellicle 200 includes several of the same or similar features of the pellicle 108 as set forth above. The same or similar features between the pellicle 200 as shown in FIG. 3A and the pellicle 108 as shown in FIGS. 2A-2D are provided with the same or similar reference numerals. For the sake of simplicity and brevity of the present disclosure, the features that are the same or similar between the pellicle 200 and the pellicle 108 may not be reproduced herein. Instead, the following discussion will focus on the different or additional features of the pellicle 200 relative to the pellicle 108.

The pellicle 200 includes the frame 108a and the pellicle membrane 108b, and the pellicle membrane 200 is coupled to the pellicle frame 108a. The pellicle 200 includes a plurality of sidewalls 202a, 202b, 202c, 202d, and the plurality of sidewalls 202a, 202b, 202c, 202d includes a first sidewall 202a, a second sidewall 202b transverse to the first sidewall 202a, a third sidewall 202c transverse to the second sidewall 202b and opposite to the first sidewall 202a, and a fourth sidewall 202d is transverse to the third sidewall 202c and is opposite to the second sidewall 202b. As shown in FIG. 3A, the first sidewall 202a, the second sidewall 202b, the third sidewall 202c, and the fourth sidewall 202d define the rectangular shape of the frame 108a of the pellicle 200. The frame 108a of the pellicle 200 has four sidewalls as the pellicle 200 has a rectangular profile. In some alternative embodiments, the pellicle 200 has some other profile with some other shape (i.e., a trapezoid, a circle, an oval, or some other type of shape or polygon). A pair of pin openings 204 are present along the first sidewall 202a of the plurality of sidewalls 202a-202d of the frame 108a, and a pair of marks or markers 206 are along the first sidewall 202a of the plurality of sidewalls 202a-202d.

In this embodiment of the pellicle 200, the pair of marks 206 are between and spaced inward from the pair of pin openings 204. In some alternative embodiments of the pellicle, only one of the pair of marks 206 is between the pair of pin openings 204 and the other one of the pair of marks 206 is between a respective transverse sidewall (i.e., the second sidewall 202b or the fourth sidewall 202d) transverse to the first sidewall 202a and the corresponding opening of the pair of pin openings 204. In yet another alternative embodiment, both the pair of marks 206 are spaced outward from the pair of openings 204 such that neither of the pair of marks 206 is between the pair of pin openings 204, and, instead, each respective mark of the pair of marks 206 are between a corresponding transverse sidewall (i.e., the second sidewall 202b or the fourth sidewall 202d) and a corresponding pin opening of the pair of pin openings 204.

While not shown in FIG. 3A, the pellicle 200 includes another pair of pin openings 204 along the third sidewall 202c and another pair of marks 206 along the third sidewall 202c. The another pair of pin openings 204 and the another pair of marks 206 along the third sidewall 202c may have the same configuration identical to that of the pair of pin openings 204 and the pair of marks 206 as shown in FIG. 3A along the first sidewall 202a, or may have some other type of configuration that is different to that of the pair of pin openings 204 and the pair of marks 206 as shown in FIG. 3A along the first sidewall 202a. In yet some other alternative embodiments, any number of the pin openings 204 and the marks 206 are along any number of the plurality of sidewalls 202a-202d. For example, other embodiments of the pellicle 200, there are respective pin openings 204 and respective marks 206 along all of the plurality of sidewalls 202a-202d of the frame 108a of the pellicle 200, there is at least one respective pin opening 204 and at least one respective mark 206 along at least two of the plurality of sidewalls 202a-202d, or any number of the pin openings 204 and any number of the marks 206 are present along any number or combination of the plurality of sidewalls 202a-202d.

Each respective mark of the pair of marks 206 has a cross-shape or a plus-shape like profile. However, in some other embodiments of the pellicle 200, a first respective mark of the pair of marks 206 may have a fist shape and a respective mark of the pair of marks 206 has a second shape different from the first shape. In some other embodiments, any number of shapes or profiles for the marks 206 can be utilized for any number of the marks 206 along any number of the plurality of sidewalls 202a-202d of the frame 108a of the pellicle 200.

As shown in FIG. 3B, the mark 206 is in relatively close proximity to the pin opening 204 that is in closer proximity to the fourth sidewall 202d than the second sidewall 202b. The mark 206 is in close proximity to the pin opening 206 as the mark 206 is configured to, in operation, be detected by a system (see FIG. 4 of the present disclosure). to confirm that the frame 108a of the pellicle 200 is in the proper position to be picked up by a respective clamp component (e.g., the clamp component 126 as discussed earlier herein).

FIG. 4 is a perspective view of a system 300 for detecting one the marks 206 along and on frame 108a the pellicle 200 as shown in FIGS. 3A and 3B, in accordance with some embodiments. As shown in the system 300, the pellicle 200 is resting on the surface 116 of the pellicle case 109. The system 300 further includes one or more detectors 302 that are configured to, in operation, detect the one or more marks 206 along the frame 108a of the pellicle 200.

In at least one embodiment of the system 300, the one or more detectors 302 are cameras that have a field of view (FOV) for detecting the marks 206 along one or more respective sidewalls of the plurality of sidewalls 202a-202d. As shown in FIG. 4, there are four cameras (i.e., the one or more detectors 302) and each respective camera of the cameras is configured to, in operation, detect a corresponding one of the marks 206 along the respective sidewalls of the plurality of sidewalls 202a-202d. In other words, while not readily visible, there are four of the marks 206 with a first pair of the marks 206 along the first sidewall 202a, and a second pair of the marks 206 along the third sidewall 202c (not readily visible in FIG. 4).

In at least some other alternative embodiments of the system 300, the one or more detectors 302 can at least be one of the following or a combination of a laser detector or some other suitable type of visual detector that allows for the one or more marks 206 to be detected by the one or more detectors 302.

In at least one embodiment in which the pellicle 200 does not include the one or more marks 206 and only includes the pin holes 204, the one or more detectors 302 are configured to, in operation, to detect the one or more pin holes 204. In other words, instead of detecting the marks 206, the one or more detectors 302 detect the one or more pin holes 204 instead to determine the position of the pellicle 200 on the surface 114 of the pellicle case 109.

The system 300 further includes a processor 304 that is in electrical communication with the one or more detectors 302. The processor 304 is configured to, in operation, receive and send signals from and to the one or more detectors 302 for determining a position of the pellicle 208 on the surface 114 of the pellicle case 109.

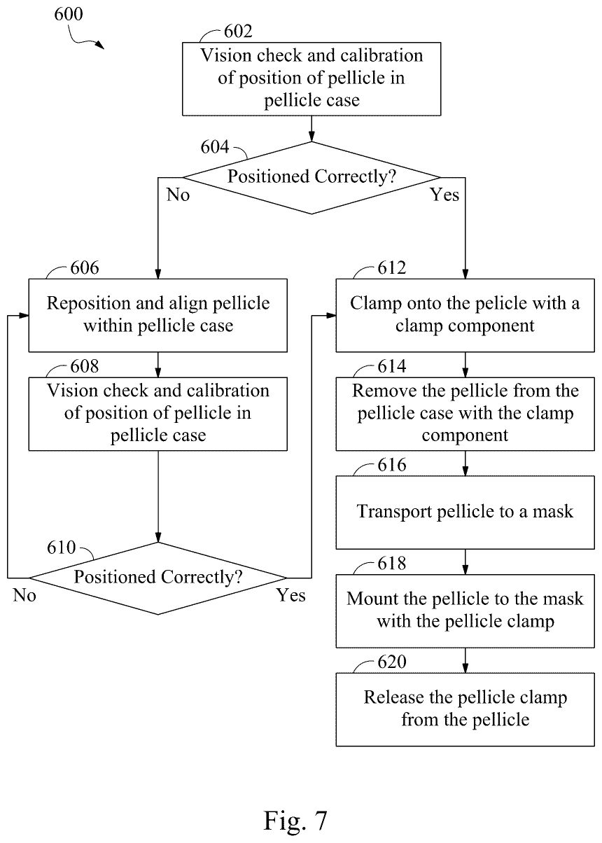

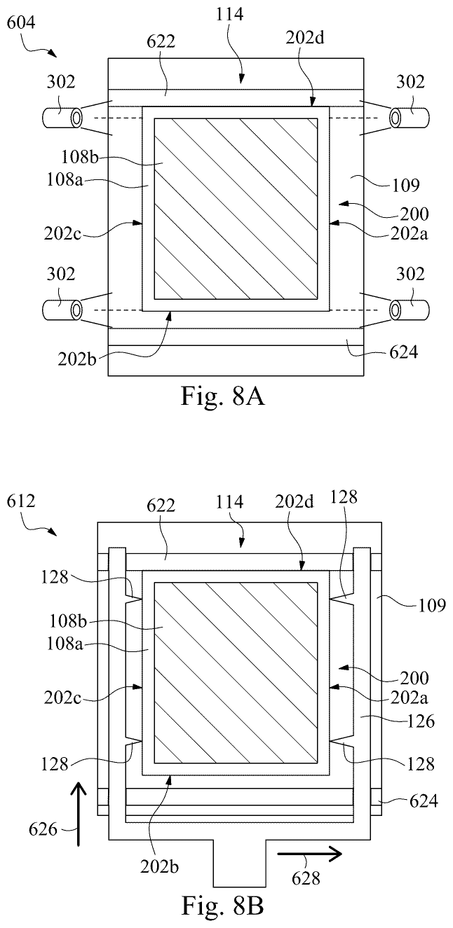

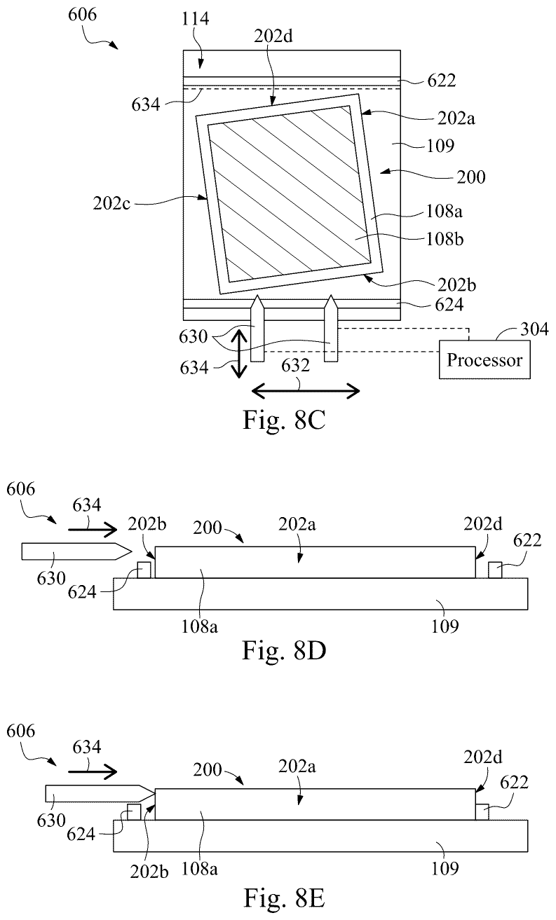

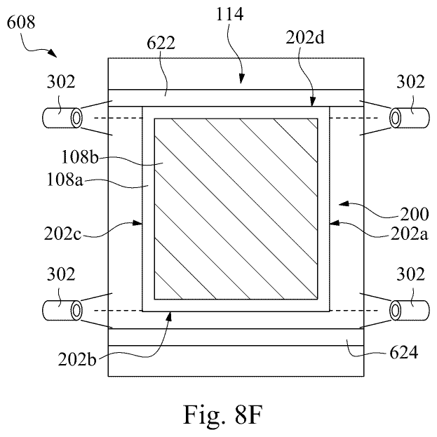

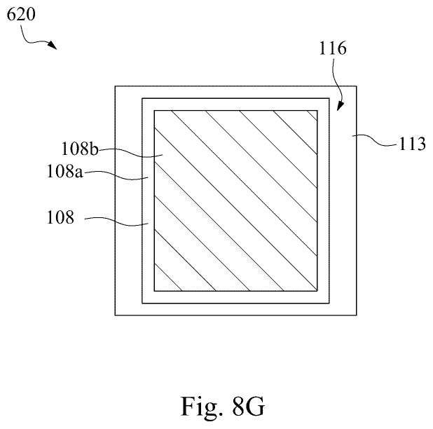

While not shown, in at least one embodiment of the system 300, the one or more detectors 302 are readily incorporated along the clamp component 126 to initially determine whether the pellicle 208 is properly positioned on the surface 114 of the pellicle case 109. While not shown, in at least one alternative embodiment of the system 300, the one or more detectors 302 are readily incorporated along an end effector of a transfer arm robot (TRA) such that the one or more detectors 302 can be utilized to determine whether the pellicle 208 is properly positioned within the pellicle case 109 along the surface 114 of the pellicle case 109 before engaging the plurality of pins 128 of the clamp component 126 with the plurality of pin openings 204 along respective sidewalls of the plurality of sidewalls 202a-202d of the frame 108a of the pellicle 208. While not shown, in at least one alternative embodiment of the system 300, the one or more detectors 302 are stationarily mounted such that the pellicle case 109 on which the pellicle 200 is present is positioned between to determine the position of the pellicle 200 along the surface 114 of the pellicle case 109. The details of performing this determination of the position of the pellicle 200 when present on the surface 114 of the pellicle case 109 will be discussed in greater detail with respect to FIGS. 7 and 8A-8G of the present disclosure later herein.

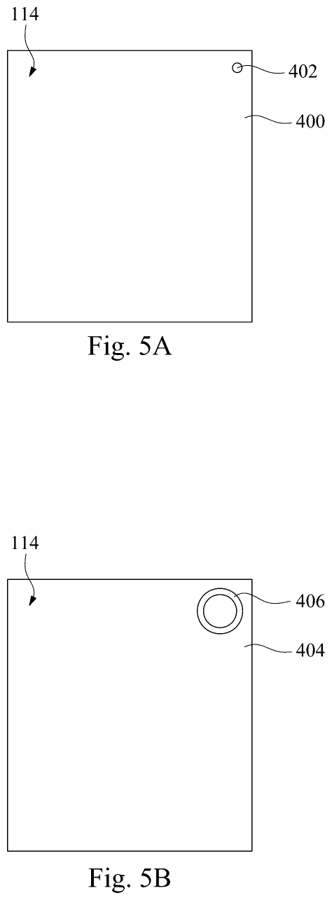

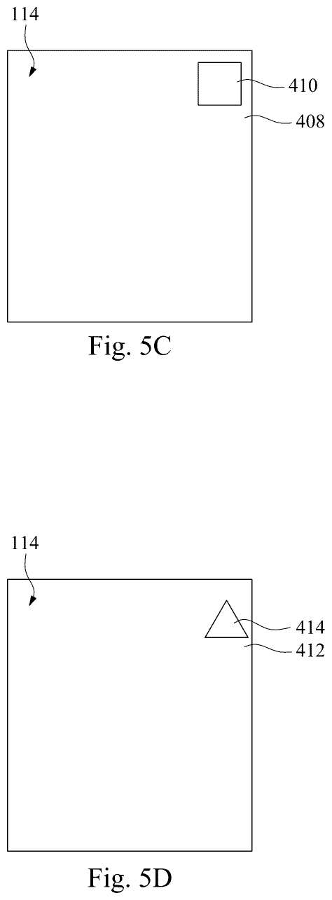

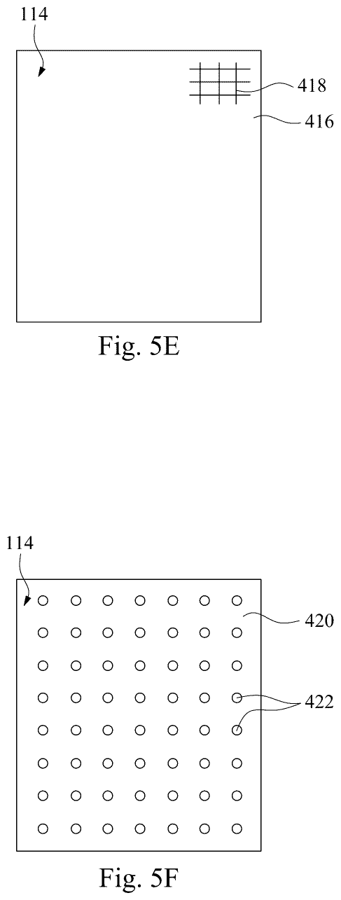

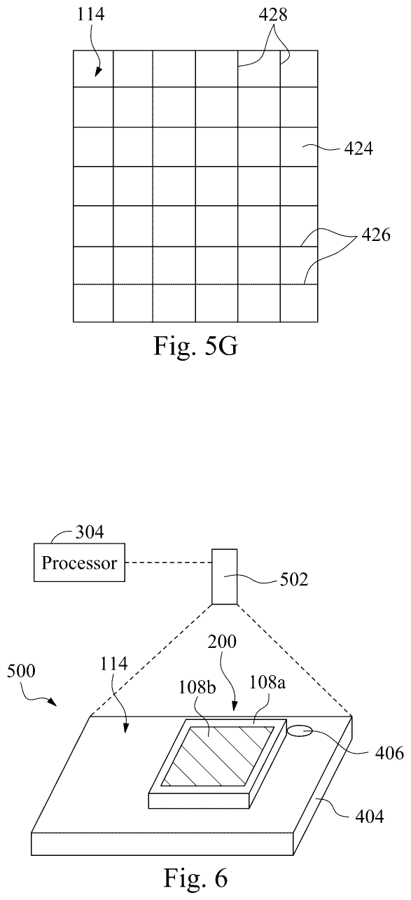

FIG. 5A is directed to a top side view of a pellicle case 400, in accordance with some embodiments. The pellicle case 400 is the same or similar to the pellicle case 109. However, unlike the pellicle case 109, the pellicle case 400 has at least one mark 402 present along the surface 114 of the pellicle case 400. As shown in FIG. 5A, the mark 402 is in close proximity to upper right-hand corner of the pellicle case 400, and the mark 402 is a circular dot. In some alternative embodiments of the pellicle case 400, the mark 402 is positioned at a different location along the surface 114 of the pellicle case 402 than as shown in FIG. 5A. In some alternative embodiments of the pellicle case 400, there is more than one of the marks 402 along the surface 114 of the pellicle case 400.

FIG. 5B is directed to a top side view of a pellicle case 404, in accordance with some embodiments. The pellicle case 404 is the same or similar to the pellicle case 109. However, unlike the pellicle case 109, the pellicle case 404 has at least one mark 406 present along the surface 114 of the pellicle case 404. As shown in FIG. 5B, the mark 406 is in close proximity to upper right-hand corner of the pellicle case 404, and the mark 406 is a hollow circle. In some alternative embodiments of the pellicle case 404, the mark 406 is positioned at a different location along the surface 114 of the pellicle case 404 than as shown in FIG. 5B. In some alternative embodiments of the pellicle case 404, there is more than one of the marks 406 along the surface 114 of the pellicle case 404.

FIG. 5C is directed to a top side view of a pellicle case 408, in accordance with some embodiments. The pellicle case 408 is the same or similar to the pellicle case 109. However, unlike the pellicle case 109, the pellicle case 408 has at least one mark 410 present along the surface 114 of the pellicle case 408. As shown in FIG. 5C, the mark 410 is in close proximity to upper right-hand corner of the pellicle case 408, and the mark 410 is a filled in square or rectangle. In some alternative embodiments of the pellicle case 408, the mark 410 is a hollowed out square or rectangle. In some alternative embodiments of the pellicle case 408, the mark 410 is positioned at a different location along the surface 114 of the pellicle case 408 than as shown in FIG. 5C. In some alternative embodiments of the pellicle case 408, there is more than one of the marks 410 along the surface 114 of the pellicle case 408.

FIG. 5D is directed to a top side view of a pellicle case 412, in accordance with some embodiments. The pellicle case 412 is the same or similar to the pellicle case 109. However, unlike the pellicle case 109, the pellicle case 412 has at least one mark 414 present along the surface 114 of the pellicle case 412. As shown in FIG. 5D, the mark 414 is in close proximity to upper right-hand corner of the pellicle case 412, and the mark 414 is a filled in triangle. In some alternative embodiments of the pellicle case 412, the mark 414 is a hollowed out triangle. In some alternative embodiments of the pellicle case 412, the mark 414 is positioned at a different location along the surface 114 of the pellicle case 412 than as shown in FIG. 5D. In some alternative embodiments of the pellicle case 412, there is more than one of the marks 414 along the surface 114 of the pellicle case 412.

FIG. 5E is directed to a top side view of a pellicle case 416, in accordance with some embodiments. The pellicle case 416 is the same or similar to the pellicle case 109. However, unlike the pellicle case 109, the pellicle case 416 has at least one mark 418 present along the surface 114 of the pellicle case 416. As shown in FIG. 5E, the mark 418 is in close proximity to upper right-hand corner of the pellicle case 416, and the mark 418 is a cross-hatched pattern. In some alternative embodiments of the pellicle case 412, the mark 418 is a plus-shape or some other suitable type of intersection of a plurality of lines. In some alternative embodiments of the pellicle case 416, the mark 418 is positioned at a different location along the surface 114 of the pellicle case 416 than as shown in FIG. 5E. In some alternative embodiments of the pellicle case 416, there is more than one of the marks 418 along the surface 114 of the pellicle case 416.

FIG. 5F is directed to a top side view of a pellicle case 420, in accordance with some embodiments. The pellicle case 420 is the same or similar to the pellicle case 109. However, unlike the pellicle case 109, the pellicle case 420 has a plurality of marks 422 present along the surface 114 of the pellicle case 420. As shown in FIG. 5D, the plurality of marks 422 are spread out evenly across the surface 114 of the pellicle case 420, and the plurality of marks 422 are circular dots. In some alternative embodiments of the pellicle case 412, the plurality of marks 422 are squares, rectangles, triangles, or some other suitable type of filled in or hollowed out shape. In some alternative embodiments of the pellicle case 420, respective marks of the plurality of marks 422 are positioned in an asymmetrical pattern instead of an array or a symmetrical pattern as shown in FIG. 5F.

FIG. 5G is directed to a top side view of a pellicle case 424, in accordance with some embodiments. The pellicle case 424 is the same or similar to the pellicle case 109. However, unlike the pellicle case 109, the pellicle case 424 has a plurality of first marks 426 and a plurality of second marks 428 present along the surface 114 of the pellicle case 424. As shown in FIG. 5G, the plurality of first marks 426 and the plurality of second marks 428 are spread out evenly across the surface 114 of the pellicle case 424, and the plurality of first marks 426 and the plurality of second marks 428 are lines that cross over each other. For example, the plurality of first marks 426 are horizontal lines based on the orientation of the pellicle case 424 as shown in FIG. 5G, and the plurality of second marks 428 are vertical lines based on the orientation of the pellicle case 424 as shown in FIG. 5G. In some alternative embodiments of the pellicle case 424, only one of the plurality of first marks 426 or the plurality of second marks 428 is present. In some alternative embodiments of the pellicle case 424, the plurality of first marks 426 and the plurality of second marks 428 are at a different angel relative to each other than as shown in FIG. 5G. For example, while the plurality of first marks 426 and the plurality of second marks 428 are perpendicular or orthogonal to each other as shown in FIG. 5G, in some alternative embodiments of the pellicle case 424, the plurality of marks are not perpendicular or orthogonal to each other and are at some other suitable angle such as a 45 degree angle, a 50 degree angle, or some other suitable angle.

The respective marks 402, 406, 410, 414, 418, 422, 426, 428 as shown in the various embodiments of the pellicle case 400, 404, 408, 412, 416, 420, 424 are utilized by a system (see FIG. 6 of the present disclosure) to determine a position of the pellicle 200 when present on the surface 114 of the respective pellicle case 400, 404, 408, 412, 416, 420, 424 and utilizing the respective marks 402, 406, 410, 414, 418, 422, 426, 428.

FIG. 6 is a perspective view of a system 500, in accordance with some embodiments. The system 500 is similar to the system 300 as discussed earlier herein. However, unlike the system 300, the system 500 includes a detector 502, which may be the same type of detector as the plurality of detectors 302. However, unlike how the detectors 302 are configured to, in operation, detect the one or more marks 206 along the respective sidewalls of the plurality of sidewalls 202a-202d, the detector 502 is configured to, in operation, detect the mark 406 along the surface 114 of the pellicle case 404. While not shown in FIG. 6, in at least one embodiment of the system 500, the detector 502 is coupled to an end effector of a transfer arm robot (TRA) such that the detector 502 can be readily positioned to view the surface 114 of the pellicle case 404. While not shown in FIG. 6, in at least one embodiment of the system 500, the detector 502 is stationarily mounted and the pellicle case 404 on which the pellicle 200 is present is positioned underneath the stationarily mounted detector 502. While not shown, in at least one alternative embodiment of the system 500, the detector 502 is one of a plurality of detectors 502, and the plurality of detectors 502 can be positioned in various positions to provide different views of the surface 114 of the pellicle case 404 to more accurately and readily determine a position of the pellicle 200 present on the surface 114 of the pellicle case 404 relative to the mark 406 along the surface 114 of the pellicle case 404.

FIG. 7 is a flowchart 600 of a method of determining and calibrating a position of the pellicle 200 within a respective embodiment of a pellicle case and mounting the pellicle 200 to the mask 113, in accordance with some embodiments. The flowchart 600 includes a plurality of steps 602-620 having a first step 602, a second step 604, a third step 606, a fourth step 608, a fifth step 610, a sixth step 612, a seventh step 614, an eight step 616, a ninth step 618, and a tenth step 620. FIGS. 8A-8G are respective top side views of the system 300 during respective steps of the plurality of steps 602-620 of the flowchart 600. The details of FIGS. 8A-8G will be discussed in tandem with the respective steps of the plurality of steps 602-620 of the flowchart 600.

In a first step 602, the one or more detectors 302 of the system 300 are brought into proximity of the pellicle case 109 and the pellicle 200 present on the surface 114 of the pellicle case 109. When the one or more detectors 302 are incorporated with the clamp component 126, the clamp component 126 is brought into close proximity to the pellicle 200 such that the one or more detectors 302 can scan for the marks 206 along the first sidewall 202a and the third sidewall 202c of the plurality of sidewalls 202 of the frame 108a of the pellicle 200. Alternatively, when the one or more detectors 302 are incorporated with an end effector of a transfer arm robot (TRA), the end effector of the TRA is brought into proximity to the pellicle 200 such that the one or more detectors 302 can scan for the marks 206 along the first sidewall 202a and the third sidewall 202c of the plurality of sidewalls 202 of the frame 108a of the pellicle 200. Alternatively, when the one or more detectors 302 are stationarily mounted, the pellicle case 109 and the pellicle 200 which is resting on the surface 114 of the pellicle case 109 are brought into close proximity by a TRA or some other transport means such that the one or more detectors 302 can scan for the marks 206 along the first sidewall 202a and the third sidewall 202c of the plurality of sidewalls 202 of the frame 108a of the pellicle 200.

While not shown in FIG. 4, the pellicle case 109 as shown in FIG. 8A includes a first barrier structure or protrusion 622 and a second barrier structure or protrusion 624 that protrude or extend outward from the surface 114 of the pellicle case 109. In some alternative embodiments of the pellicle case 109, there may be only one of the first or second barrier structures or protrusions 622, 624. In some alternative embodiments of the pellicle case 109, there may be more than just the first and second barrier structures or protrusions 622, 624, for example, there may be three respective barrier structures or protrusions, there may be four respective barrier structures or protrusions, or there may be some other suitable number of the respective barrier structures or protrusions.

Once the pellicle 200 and the pellicle case 109 are in close proximity with the one or more detectors 302, the one or more detectors 302 are activated to scan for the one or more marks 206 along the first sidewall 202a and the third sidewall 202c of the plurality of sidewalls 202a-202d of the frame 108a of the pellicle 200. For example, the processor 304 sends one or more controls signals to the one or more detectors 302 to activate the one or more detectors 302.

Once activated, the one or more detectors 302 scan for the marks 206. The one or more detectors 302 then send one or more data signals to the processor 304 such that the processor 304 can analyze these one or more data signals in a second step 604 to determine a position of the pellicle 200 present on the surface 114 of the pellicle case 109. There are two outcomes of this analysis by the processor in that either (1) the pellicle 200 is determined to be positioned in an appropriate position for the pins 128 of the clamp component 126 to be inserted into the pin holes 204 along the first sidewall 202a and the third sidewall 202c or (2) the pellicle 200 is determined to be mis-positioned such that the pellicle 200 needs to be repositioned.

When the pellicle 200 is determined to be properly positioned in the second step 604 such that the pins 128 can be inserted into the pin holes 204, the flowchart proceeds directly to the sixth step 612. In the sixth step 612, the clamp component 126 is positioned as represented by arrows 626, 628 such that the plurality of pins 128 are aligned with the plurality of pin holes 204 as shown in FIG. 8B. Once the clamp component 126 is properly positioned and the pins 128 are properly aligned with the pin holes 204, the clamp component 126 is actuated to insert the pins 128 into the pin holes 204. In some embodiments of the flowchart 600, before inserting the pins 128 into the pin holes 204, the one or more detectors 302 are moved away from the pellicle 200 and the pellicle case 109. In some embodiments of the flowchart 600, before inserting the pins 128 into the pin holes 204, the one or more detectors 302 remain in close proximity to the pellicle 200 and pellicle case 109 when the one or more detectors 302 are incorporated along, on, or in the clamp component 126. In some embodiments of the flowchart 600, before inserting the pins 128 into the pin holes 204, the pellicle 200 and the pellicle case 109 are moved away from the one or more detectors 302 as the one or more detectors 302 are stationarily mounted. In some embodiments of the flowchart 600, before inserting the pins 128 into the pin holes 204, the pellicle 200 and the pellicle case 109 remain in close proximity to the one or more detectors 302 even when stationarily mounted.

After the sixth step 612 in which the pins 128 of the clamp component 126 are inserted into the pin holes 204, in the seventh step 614 the pellicle 200 is removed from the surface 114 of the pellicle case 109 by moving the clamp component 126 in a direction directed away from the surface 114 of the pellicle case 109 lifting the pellicle 200 from the surface 114 of the pellicle case 109.

After the seventh step 614 in which the pellicle 200 is removed from the surface 114 by the clamp component 126, in the eighth step 616 the pellicle 200 is transported to the mask 113. The pellicle 200 is then aligned to overlap and be positioned over the mask 113.

After the eighth step 616 in which the pellicle 200 is aligned with and overlapping the surface 116 of the mask 113, in a ninth step 618 an the clamp component 126 is moved downward towards the surface 116 of the mask 113 until the frame 108a of the pellicle 200 is mounted to the surface 116 of the mask 113. While not shown, in at least one embodiment, an adhesive is pre-applied to the surface 116 of the mask 113 such that when the frame is placed on the surface 116 of the mask 113, the frame 108a of the pellicle 200 is adhered to the surface 116 of the mask 113. Once the frame 108a of the pellicle 200 is mounted to the surface 116 of the mask 113, the pellicle membrane 108b is overlapping and extending across a pattern along the surface 116 of the mask 113 such that the pellicle membrane 108b acts a barrier preventing contaminants or particles from reaching the pattern along the surface 116 of the mask 113.

After the ninth step 618 in which the frame 108a of the pellicle 200 has been mounted to the surface 116 of the mask 113 such that the frame 108a is mounted to the surface 116 of the pellicle 200 and the pellicle membrane 108a acts as the barrier for the pattern along the surface 116 of the mask 113, in the tenth step 620 the clamp component 126 is actuated such that the plurality of pins 128 of the clamp component 126 are removed from the pin holes 204 in the frame 108a of the pellicle. After the pins 128 have been removed from the pin holes 204, the clamp component 126 is moved away from the pellicle 200 now mounted to the surface 116 of the mask 113. The result of the tenth step 620 in which the frame 108a of the pellicle 200 is mounted to the surface 116 of the mask 113 is readily visible in FIG. 8G.

When the pellicle 200 is determined to be not be properly positioned (i.e., mis-positioned) in the second step 604 such that the pins 128 cannot be properly inserted without an increased likelihood of damaging the pellicle 200 or an increased likelihood of unevenly or non-uniformly picking up the pellicle 200. Either of these issues occurring can result in damage to the pattern into the pin holes 204, the flowchart proceeds directly to the third step 606 instead of the sixth step 612.

In the third step 606, the pellicle 200 is repositioned to or towards the proper position as the pellicle 200 was determined to be in improperly positioned along the surface 114 of the pellicle case 109 as shown in FIGS. 8C-8E. The pellicle 200 is repositioned to or towards the proper position by utilizing one or more push components 630 with pointed ends 631 as shown in FIG. 8C. Unlike the pair of push components 118 as discussed earlier herein that are not movable individually, are only movable in the direction as represented by the arrows 120 in FIG. 2B, and are not movable in the horizontal direction, the one or more push components 630 are movable individually and separately and are movable both vertically and horizontally based on the orientation as shown in FIG. 8C, as well as represented by arrows 632, 634. As the one or more push components 630 are separately moveable from one another, the pellicle 200 can be more precisely repositioned to the proper position before being picked up by the clamp component 126. As the one or more push components 630 are separately movable, the likelihood of damage to the pellicle 200 (i.e., bending or deforming the frame 108a of the pellicle 200) is reduced relative to when the push components 118, which are not individually movable, are utilized to reposition the pellicle 200. For the pellicle 200 to be properly positioned, the pellicle should be at a dotted line 636 as shown in FIG. 8C. The dotted line 636 is directly adjacent or abutting the first barrier structure or protrusion 622 extending outward from the surface 114 of the pellicle case 109.

As shown in FIG. 8C, the pellicle 200 is left such that the pellicle 200 is both misaligned and improperly positioned along and on the surface 114 of the pellicle case 109. The processor 304 is in electrical communication with the one or more push components 630. In at least some embodiments, the processor 304 sends control signals to the one or more push components 630 based on the one or more data signals received from the one or more detectors 302 after determining the pellicle 200 is misaligned and improperly positioned on the surface 114 of the pellicle case 109. At least one of the push components 630 is actuated to move the pellicle 200 to the proper position as represented by the dotted line 636. For example, as shown in FIG. 8D, the one or more push component 630 closer to the left-hand side of FIG. 8C is actuated and moved in the direction as represented by the arrow 634 as shown in FIGS. 8D and 8E until the end of the push component 630 contacts the second sidewall 202b of the plurality of sidewalls 202a-202d of the frame 108a of the pellicle 200. The push component 630 then continues to move in the direction 634 after coming into contact with the second sidewall of the pellicle 200 rotating and moving the pellicle 200 towards the proper position as represented by the dotted line 636 as shown in FIG. 8C. At a certain point during this process, the other push component 630 which is closer to the right-hand side of FIG. 8C may be brought into contact with the second sidewall 202b of the frame 108a of the pellicle 200 to assist in moving the pellicle to the proper position as represented by the dotted line 636 as shown in FIG. 8C.

As shown in FIGS. 8C-8E, the first barrier structure or protrusion 622 and the second barrier structure or protrusion 624 protruding from the surface 114 of the pellicle case 109 prevent or reduce the likelihood of the pellicle 200 from falling off the surface 114 of the pellicle case 109. Furthermore, as shown in FIG. 8E, the first barrier structure or protrusion 622 allows for the pellicle 200 to be properly positioned and remain properly positioned at the position as represented by the dotted line 636. For example, as the pellicle 200 is moved from the improper position as shown in FIG. 8C to the proper position as shown in FIGS. 8E and 8F, the fourth sidewall 202d may and can abut the first barrier structure or protrusion 622.

After the third step 606 in which the pellicle 200 was repositioned from the improper position as shown in FIG. 8C to the proper position as shown in FIG. 8F, in a fourth step 608 and the fifth step 610, the one or more detectors 302 are brought back in close proximity to the pellicle 200 and the pellicle case 109 such that the one or more detectors can scan for the one or more marks along the respective sidewalls of the plurality of sidewalls 202a-202d of the frame 108a of the pellicle 200. The processor 304 then receives data signals from the one or more detectors 302 to determine whether the pellicle 200 is in the proper position. In other words, the same process is performed as was previously performed in the first step 602 and the second step 604 is reperformed in the fourth step 608 and the fifth step 610. However, if the processor 304 determines from the data signals that the pellicle 200 is still not in the proper position as shown in FIGS. 8B and 8F, the third step 606 and the fourth step 608 are reperformed until the pellicle 200 is in the proper position as represented by the dotted line 636 as shown in FIG. 8C. If the cycle of the third step 606, the fourth step 608, and the fifth step 610 are performed enough times, the flowchart 600 may be stopped such that an employee of a semiconductor manufacturing plant (FAB) can personally inspect an issue with the pellicle 200 and pellicle case 109. Once the pellicle is determined to be in the proper position at the dotted line 636 as shown in FIGS. 8B and 8F as represented by the dotted line 636 as shown in FIG. 8C, the sixth, seventh, eighth, ninth, and tenth steps 612, 614, 616, 618, 620 are performed such that the pellicle 200 is mounted to the surface 116 of the mask 113.

When the system 500 is instead utilized instead of the system 300, the one or more detectors 502 are utilized along with the processor 304, which is in electrical communication with the one or more detectors 502, to determine the position of the pellicle 200 relative to the respective marks 402, 406, 410, 414, 418, 422, 426, 428. Otherwise, the process of the flowchart 600 when utilizing the system 300 is the same when utilizing the system 500, but the position of the pellicle 200 along the surface 114 of the pellicle case 109 is done in a slightly different fashion.

For example, when the system 500 is utilized to determine the position of the pellicle 200 present on the surface 114 of the pellicle case 109, in the first step 602 the detector 502 scans for the mark 406 to determine the position of the pellicle 200 relative to the mark 406. In at least one situation, when the detector 502 detects that part of the mark 406 is interrupted (i.e., not fully visible by the detector 502), the detector 502 sends a signa to the processor 304. The data signal output by the detector 502 is then analyzed by the processor in the second step 604 to determine whether the pellicle is positioned properly or correctly or is improperly positioned along the surface 114 of the pellicle case 109.

If the processor 304 in the second step 604 determines that the pellicle 200 is in the proper position along the surface 114 of the pellicle case 109, the flowchart 600 proceeds to performing the sixth, seventh, eighth, ninth, and tenth steps 612, 614, 515, 618, 620, which were previously discussed in detail earlier herein with respect to utilizing the system 300 when performing the method of the flowchart 600. Alternatively, if the processor 304 in the second step 604 determines that the pellicle 200 is improperly positioned, the flowchart 600 proceeds to performing the third, fourth, and fifth steps 606, 608, 610, which were previously discussed in detail earlier herein with respect to utilizing the system 300 when performing the method of the flowchart 600.

In some embodiments of the method of the flowchart 600 for calibrating the position of the pellicle 200, during the second step 604, if misalignment is detected by the one or more detector 302 to be too large, the detector 302 may not be able to capture the image of pin hole 204, the mark 206, or both. If this is detected by the one or more detectors 302 and determined by the processor 304, the third step 606, the fourth step 608, and the fifth step 610 are looped such that the one or more push components 630 reposition the pellicle 200 multiple times until in a rough alignment position. Once the pellicle 200 is in a rough alignment position utilizing the one or more push components 630, a TRA (transfer robot arm) can be utilized to provide further precision alignment before initiating the sixth step 612 in which the pins 128 of the clamp 126 are inserted into the pin holes 204 along the frame 108a of the pellicle 200. The one or more detectors 302 can be utilized to assist the TRA to provide these precision adjustments to the pellicles 200 position and alignment. Utilizing the TRA to provide further precisions adjustment in position and alignment further reduces the likelihood of or prevents defects or issues occurring when mounting the pellicle 200 to the mask 113. In this alternative embodiment of the method of the flowchart 600, the one or more push components 630 provide rough alignment in the direction as represented by the arrow 634 while the TRA provide precision or fine positioning and alignment adjustment in the direction as represented by the arrow 634 and the direction as represented by the arrow 632.

In some embodiments of the method of the flowchart 600 for calibrating the position of the pellicle 200, during the sixth step 612, the one or more detectors 302 are utilized to assist in aligning the pins 128 of the clamp 126 with the pin holes 204 along the frame 108a of the pellicle 200. Utilizing the one or more detectors 302 to engage the clamp 126 with the frame 108a of the pellicle 200 further reduces the likelihood of or prevents defects or issues occurring when mounting the pellicle 200 to the mask 113.

In at least one embodiment of the system 500, the detector 502 and the mark 406 are utilized to confirm a position of the pellicle case 404 when present on a stage (not shown) of transport equipment such as a TRA (transfer robot arm), a clamp, or some other similar or like type of transport equipment or combination or transport equipment. In some embodiments, once the pellicle case 404 is positioned appropriately utilizing the detector 502 and the mark 406, the pellicle 200 is positioned along the surface 114 of the pellicle case 406 by utilizing the detector 502 and the mark 406.

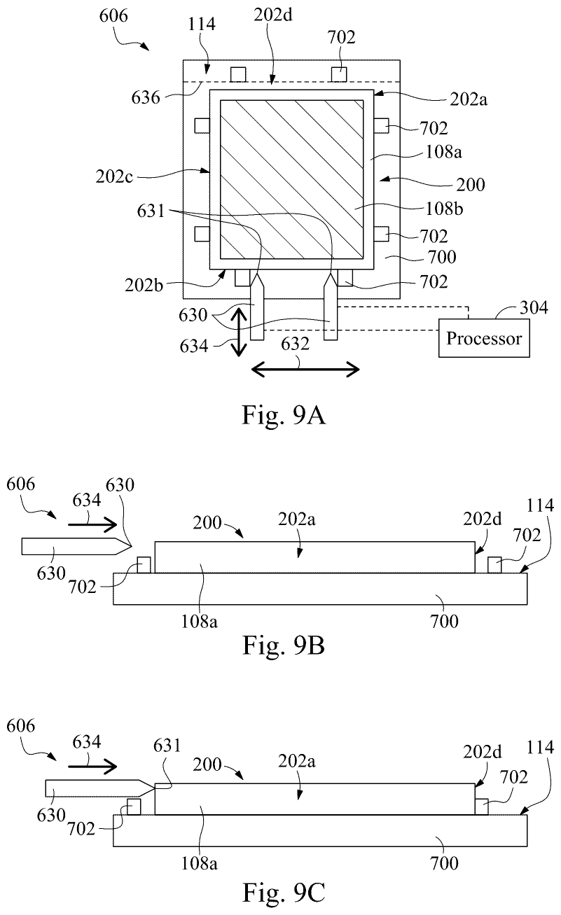

FIG. 9A is a top side view of a system with respect to the third step 606 of the method of calibrating 600 the position of the pellicle 200 within an alternative embodiment of a pellicle case 700 and mounting the pellicle to the mask as shown in FIG. 7, in accordance with some embodiments. The pellicle 200 is repositioned to or towards the proper position by utilizing one or more push components 630 as shown in FIG. 9A. Unlike the pair of push components 118 as discussed earlier herein that are not movable individually, are only movable in the direction as represented by the arrows 120 in FIG. 2B, and are not movable in the horizontal direction, the one or more push components 630 are movable individually and separately and are movable both vertically and horizontally based on the orientation as shown in FIG. 9A, as well as represented by arrows 632, 634. As the one or more push components 630 are separately moveable from one another, the pellicle 200 can be more precisely repositioned to the proper position before being picked up by the clamp component 126. As the one or more push components 630 are separately movable, the likelihood of damage to the pellicle 200 (i.e., bending or deforming the frame 108a of the pellicle 200) is reduced relative to when the push components 118, which are not individually movable, are utilized to reposition the pellicle 200. For the pellicle 200 to be properly positioned, the pellicle 200 should be at a dotted line 636 as shown in FIG. 9A. The dotted line 636 is directly adjacent or abutting a pair of a plurality of barrier protrusions 702 extending outward from the surface 114 of the pellicle case 700.

Unlike the pellicle case 109 that includes the first barrier structure or protrusion 622 and the second barrier structure or protrusion 624 that extend across the surface 114 of the pellicle case 109 to opposite sides of the pellicle case 700, the alternative embodiment of the pellicle case 700 as shown in FIG. 9A includes the plurality of barrier protrusions 702 that extend outward from the surface of the pellicle case 700. In this embodiment, the plurality of barrier protrusions 702 includes six respective barrier protrusions 702. Respective pairs of the plurality of barrier protrusions 702 are configured to, in operation, prevent or reduce the likelihood of the pellicle 200 from falling off the surface 114 of the pellicle case 700.

As shown in FIG. 9A, the pellicle 200 is left such that the pellicle 200 is both misaligned and improperly positioned along and on the surface 114 of the pellicle case 702. The processor 304 is in electrical communication with the one or more push components 630. In at least some embodiments, the processor 304 sends control signals to the one or more push components 630 based on the one or more data signals received from the one or more detectors 302 after determining the pellicle 200 is misaligned and improperly positioned on the surface 114 of the pellicle case 109. At least one of the push components 630 is actuated to move the pellicle 200 to the proper position as represented by the dotted line 636. For example, as shown in FIG. 9B, the one or more push component 630 closer to the left-hand side of FIG. 9B is actuated and moved in the direction as represented by the arrow 634 as shown in FIGS. 9B and 9C until the end of the push component 630 contacts the second sidewall 202b of the plurality of sidewalls 202a-202d of the frame 108a of the pellicle 200. The push component 630 then continues to move in the vertical direction 634 after coming into contact with the second sidewall of the pellicle 200 moving the pellicle 200 towards the proper position as represented by the dotted line 636 as shown in FIG. 9A. At a certain point during this process, the other push component 630 which is closer to the right-hand side of FIG. 9A may be brought into contact with the second sidewall 202b of the frame 108a of the pellicle 200 to assist in moving the pellicle to the proper position as represented by the dotted line 636 as shown in FIG. 9A.

As shown in FIGS. 9A-9C, the plurality of barrier protrusions 702 protruding from the surface 114 of the pellicle case 700 prevent or reduce the likelihood of the pellicle 200 from falling off the surface 114 of the pellicle case 700. Furthermore, as shown in FIGS. 9B and 9C, a respective uppermost pair of the plurality of barrier protrusions 702 allows for the pellicle 200 to be properly positioned and remain properly positioned at the position as represented by the dotted line 636 as shown in FIG. 9A. For example, as the pellicle 200 is moved from the improper position as shown in FIG. 9A to the proper position, the fourth sidewall 202d may and can abut the respective uppermost pair of the plurality of barrier protrusions 702 as shown in FIG. 9A. The respective pairs of the plurality of barrier protrusions 702 in close proximity to the left and right hand side of the pellicle 200 as shown in FIG. 9A limit horizontal movement of the pellicle 200 in the left and right directions based on the orientation as shown in FIG. 9A as represented by the arrow 632. The respective pairs of the plurality of barrier protrusions 702 in close proximity to the lowermost and uppermost side of the pellicle 200 as shown in FIG. 9A limit vertical movement of the pellicle 200 in the downward and upward directions based on the orientation as shown in FIG. 9A as represented by the arrow 634.

In view of the discussion with respect to FIGS. 9A-9C, when the third step 606 is carried out utilizing the alternative embodiment of the pellicle case 700, the process is essentially carried out the same or similar to the details as also discussed in detail earlier herein with respect to FIGS. 8C-8E, as well as the other steps of the method of calibrating the position of the pellicle 200 along the surface 114 of the pellicle case 700.

As discussed herein, when utilizing the respective embodiments of the systems 300, 500 (see FIGS. 4 and 6 of the present disclosure) along with utilizing the respective embodiments of the pellicles 200 (see FIGS. 3A and 3B of the present disclosure), the pellicle cases 400 (see FIGS. 5A-5G of the present disclosure), or a combination of both to perform the method in the embodiment of the flowchart 600, damage to any of the components or PID is reduced as compared to when utilizing the method of the flowchart 100 (see FIG. 1 of the present disclosure) with the details as discussed in FIGS. 2A-2D of the present disclosure. Foe example, since the method of the flowchart 600 checks for the position of the pellicle 200 one or more times to determine whether the pellicle 200 is properly positioned along the surface 114 of the pellicle case 109 to prevent or reduce the likelihood of the pins 128 of the clamp component 126 unevenly or non-uniformly engaging with the pin holes 204 along the respective sidewalls of the plurality of sidewalls 202a-202d, damage or PID is less likely to occur or is completely prevented when mounting the pellicle 200 to the surface 116 of the mask 113 to protect the pattern along the surface 116 of the mask 113. This is because the accuracy of which the pellicle 200 is picked up by the clamp component 126 and the accuracy of which the pellicle 200 is mounted to the surface 116 of the mask 113 is increased relative to the method of the flowchart 100 (see FIG. 1 of the present disclosure) utilizing the details as described with respect to FIGS. 2A-2D of the present disclosure. In other words, the likelihood of a wafer being patterned accurately and correctly as the pellicle 200 is more likely to be mounted accurately and correctly to the surface 116 of the mask 113 and the pellicle 200 is less likely of being deformed or damaged by improper engagement with the clamp component 126 results in the operation cots of a semiconductor manufacturing plant (FAB) as there are fewer wafers that are patterned outside of manufacturing tolerances increasing the number of semiconductor devices manufacturing within manufacturing tolerances.

At least one embodiment of a method of the present disclosure includes: performing a first position check of a pellicle in a pellicle case; when the position of pellicle is determined to be in a correct position, performing a mounting process by removing the pellicle from the pellicle case and mounting the pellicle to a mask; when the position of the pellicle is determined to be in a misaligned position, performing a repositioning process including: performing one or more successive moving steps to move the pellicle from the misaligned position to the correct position; and performing one or more successive second position checks to confirm once the pellicle is in the correct position; when the pellicle is determined to have been moved from the misaligned position to the correct position, performing the mounting process to remove the pellicle from the pellicle case and mount the pellicle to the mask.

At least one embodiment of a system of the present disclosure includes: a pellicle including one or more marks along one or more sides of the pellicle and one or more pin openings along the one or more sides of the pellicle; a pellicle case including a region in which the pellicle is stored; one or more visual cameras configured to, in operation, detect the one or more marks along the one or more sides of the pellicle; a processor in electrical communication with the one or more visual cameras, the processor is configured to, in operation, determine a position of the pellicle with visual information collected by the one or more visual cameras; a pellicle position adjustment structure in electrical communication with the processor, the pellicle position adjustment structure is configured to, in operation, move and adjust a position of the pellicle within the pellicle case; and a pellicle transport structure being in electrical communication with the processor, the pellicle transport structure including one or more pin structures configured to, in operation, engage with one or more pin openings to remove the pellicle from the pellicle case and transport the pellicle.

At least one embodiment of a system of the present disclosure includes: a pellicle including one or more pin openings along one or more sides of the pellicle; a pellicle case including a region in which the pellicle is stored, the region including one or more marks; one or more visual cameras configured to, in operation, detect the one or more marks along the region of the pellicle case; a processor in electrical communication with the one or more visual cameras, the processor is configured to, in operation, determine a position of the pellicle with visual information collected by the one or more visual cameras; a pellicle position adjustment structure in electrical communication with the processor, the pellicle position adjustment structure is configured to, in operation, move and adjust a position of the pellicle within the pellicle case; and a pellicle transport structure being in electrical communication with the processor, the pellicle transport structure including one or more pin structures configured to, in operation, engage with one or more pin openings to remove the pellicle from the pellicle case and transport the pellicle.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
performing a first position check of a pellicle in a pellicle case;
when the position of pellicle is determined to be in a correct position, performing a mounting process by removing the pellicle from the pellicle case and mounting the pellicle to a mask;
when the position of the pellicle is determined to be in a misaligned position, performing a repositioning process including:
performing one or more successive moving steps to move the pellicle from the misaligned position to the correct position; and
performing one or more successive second position checks to confirm once the pellicle is in the correct position;
when the pellicle is determined to have been moved from the misaligned position to the correct position, performing the mounting process to remove the pellicle from the pellicle case and mount the pellicle to the mask.

2. The method of claim 1, wherein performing the mounting process to remove the pellicle from the pellicle case and mount the pellicle to the mask includes:
engaging a pellicle transport structure with the pellicle when in the correct position;
after the pellicle transport structure is engaged with the pellicle, removing the pellicle from the pellicle case with the pellicle transport structure;
after the pellicle has been removed from the pellicle case, transporting the pellicle to the mask with the pellicle transport structure;
after the pellicle has been transported to the mask, mounting the pellicle to the mask;
after the pellicle has been mounted to the mask, disengaging the pellicle transport structure from the pellicle.

3. The method of claim 2, wherein:
engaging the pellicle transport structure with the pellicle includes inserting one or more pins of the pellicle transport structure into one or more pin opening along a plurality of sides of the pellicle; and
disengaging the pellicle transport structure from the pellicle includes removing the one or more pins of the pellicle transport structure from the one or more pin openings along the plurality of sides of the pellicle.

4. The method of claim 1, wherein performing one or more successive movement steps to move the pellicle from the misaligned position to the correct position includes moving the pellicle from the misaligned position to or towards the correct position with one or more pellicle adjustment structures.

5. The method of claim 1, wherein performing one or more successive movement steps to move the pellicle from the misaligned position to the correct position includes at least one of the following of:
moving the pellicle in a first direction;
moving the pellicle in a second direction transverse to the first direction;
moving the pellicle in a combination of the first direction and the second direction; or
rotating the pellicle.

6. The method of claim 1, wherein performing the first position check of the pellicle in the pellicle case includes utilizing one or more cameras to visually inspect a position of the pellicle within the pellicle case.

7. The method of claim 6, wherein utilizing the one or more cameras to visually inspect the position of the pellicle further includes monitoring one or more locations of one or more marks along one or more sides of the pellicle.

8. The method of claim 7, wherein performing the one or more successive second position checks to confirm once the pellicle in the correct position includes monitoring the one or more locations of the one or more marks along the one or more sides of the pellicle.

9. The method of claim 6, wherein utilizing the one or more cameras to visually inspect the position of the pellicle further includes monitoring one or more points along the pellicle relative to one or more marks along a pellicle case.

10. The method of claim 9, wherein performing the one or more successive second position checks to confirm once the pellicle in the correct position includes monitoring the one or more points along the pellicle relative to the one or more marks along the pellicle case.

11. The method of claim 10, wherein the one or more marks are along an interior of the pellicle case.

12. The method of claim 11, wherein the one or more marks is a single marker along the interior of the pellicle case.

13. The method of claim 11, wherein the one or more marks is an array marks along the interior of the pellicle case.

14. The method of claim 11, wherein the one or more marks a pattern of crisscrossed lines along the interior of the pellicle case.

15. A system, comprising:
a pellicle including one or more marks along one or more sides of the pellicle and one or more pin openings along the one or more sides of the pellicle;
a pellicle case including a region in which the pellicle is stored;
one or more visual cameras configured to, in operation, detect the one or more marks along the one or more sides of the pellicle;
a processor in electrical communication with the one or more visual cameras, the processor is configured to, in operation, determine a position of the pellicle with visual information collected by the one or more visual cameras;
a pellicle position adjustment structure in electrical communication with the processor, the pellicle position adjustment structure is configured to, in operation, move and adjust a position of the pellicle within the pellicle case; and
a pellicle transport structure being in electrical communication with the processor, the pellicle transport structure including one or more pin structures configured to, in operation, engage with one or more pin openings to remove the pellicle from the pellicle case and transport the pellicle.

16. The system of claim 15, wherein, when the processor determines the pellicle is in a correct position, the processor outputs a signal to the pellicle transport structure to engage the one or more pin structures with the one or more pin openings.

17. The system of claim 16, wherein, when the processor determines the pellicle is in a misaligned position, the processor outputs a signal to the pellicle position adjustment structure to move the pellicle from the misaligned position towards the correct position.

18. A system, comprising:
a pellicle including one or more pin openings along one or more sides of the pellicle;
a pellicle case including a region in which the pellicle is stored, the region including one or more marks;
one or more visual cameras configured to, in operation, detect the one or more marks along the region of the pellicle case;
a processor in electrical communication with the one or more visual cameras, the processor is configured to, in operation, determine a position of the pellicle with visual information collected by the one or more visual cameras;
a pellicle position adjustment structure in electrical communication with the processor, the pellicle position adjustment structure is configured to, in operation, move and adjust a position of the pellicle within the pellicle case; and
a pellicle transport structure being in electrical communication with the processor, the pellicle transport structure including one or more pin structures configured to, in operation, engage with one or more pin openings to remove the pellicle from the pellicle case and transport the pellicle.

19. The system of claim 18, wherein, when the processor determines the pellicle is in a correct position, the processor outputs a signal to the pellicle transport structure to engage the one or more pin structures with the one or more pin openings.

20. The system of claim 19, wherein, when the processor determines the pellicle is in a misaligned position, the processor outputs a signal to the pellicle position adjustment structure to move the pellicle from the misaligned position towards the correct position.
